(19) United States
(12) Patent Application Publication
(10) Pub. No.: US 2013/0233600 A1
(43) Pub. Date: Sep. 12, 2013

(54) INTEGRATED PLATED CIRCUIT HEAT SINK AND METHOD OF MANUFACTURE

(71) Applicant: Ling Ping Ong, Perai (MY)

(72) Inventor: Ling Ping Ong, Perai (MY)

(73) Assignee: ANOMAX SDN BHD, Perai, PN (MY)

(21) Appl. No.: 13/885,352

(22) PCT Filed: Jun. 16, 2011
(86) PCT No.: PCT/MY11/00096

§ 371 Date: May 14, 2013

(30) Foreign Application Priority Data
Dec. 23, 2010 (US) 12/977595
Feb. 14, 2011 (MY) PI 2011000669

(51) Int. Cl. H05K 3/46; H05K 1/05

(52) U.S. Cl. CPC H05K 3/46; H05K 1/05
USPC 174/255; 205/199

(57) ABSTRACT

A method of preparing a non-ferrous metal substrate for plating includes providing an anodized layer on an aluminum substrate and electrically isolating the anodized layer from the non-ferrous metal substrate by applying an electrically non-conductive micro-filler to the anodized layer to form a filled region of the anodized layer electrically isolating the anodized layer from the non-ferrous metal substrate.

### TECHNICAL FIELD

The present invention relates generally to non-ferrous metal substrates for electrical circuits, and to processes for preparing non-ferrous metal substrates for plating.

### BACKGROUND ART

Anodizing is an electrolytic passivation process that increases the thickness of the natural oxide coatings or layers on the surface of aluminum substrates. Anodizing increases corrosion and wear resistance, and provides an electrically non-conductive surface.

Anodizing changes the microscopic texture of the surface of the metal part or substrate and changes the crystal structure of the metal near the surface. Anodized layers are inherently porous, as is well-known in the art, and sealing is often employed to minimize the porosity. Anodized aluminum surfaces are harder than aluminum; generally, the thicker the anodized layer, the harder the surface and the lesser the porosity.

Anodizing aluminum substrates to form porous anodized layers as a surface pre-treatment is common and well-known. Anodized aluminum has been investigated as a di-electric material for use in electronic packaging. Thick anodized layers are prone to cracking because anodized layers have very low thermal expansion values while the attached aluminum substrate has high thermal expansion properties. The different expansion rates causes stress in the brittle anodized layer leading to cracks, and the thicker the anodized layer, the higher the chance of cracking.

Plating onto aluminum and aluminum alloys in the raw oxidized and anodized states typically results in either very poor adhesion of the plated layer or leakage of electrical current between the plated layer and the base aluminum substrate or both. This leakage of electrical current between the plated layer and the aluminum substrate through the anodized layer diminishes the operational efficiency of the electronic circuits formed by the plated layer and electronic components electrically connected to the plated layer.

### DISCLOSURE OF THE INVENTION

Methods of preparing a non-ferrous metal substrate for plating, methods of plating an electrical circuit on an anodized layer formed on a surface of a non-ferrous metal substrate, and a resulting integrated plated circuit heat sink are disclosed.

In a non-ferrous metal substrate having an anodized layer thereon, a method of preparing the anodized layer for plating includes electrically isolating the anodized layer from the non-ferrous metal substrate in a solution of an electrically non-conductive micro-filler. The step of electrically isolating the anodized layer from the non-ferrous metal substrate in the solution of the electrically non-conductive micro-filler includes submerging the anodized layer in the solution for at least approximately 5-10 minutes, removing the anodized layer from the solution, and drying the anodized layer. Submerging the anodized layer in the solution preferably includes submerging the non-ferrous metal substrate in the solution. The method still further includes removing excess solution from the anodized layer between the removing and drying steps by wiping excess solution from the anodized layer with a clean, dry, lint-free towel or squeegee or the like. To form a substrate for electrical circuits, the method next includes activating the anodized layer, and plating the anodized layer.

According to the principle of the invention, a method of preparing a non-ferrous metal substrate for plating includes providing an anodized layer on a non-ferrous metal substrate, the anodized layer having an outer surface and an opposed inner surface at the non-ferrous metal substrate, applying an electrically non-conductive micro-filler to the anodized layer to form in the anodized layer a filled region of the anodized layer between the outer and inner surfaces of the anodized layer, and leaving an unfilled region of the anodized layer between the outer surface of the anodized layer and the filled region, and the filled region electrically isolating the unfilled region from the aluminum substrate. The step of applying the electrically non-conductive micro-filler to the anodized layer preferably includes providing a solution of the electrically non-conductive micro-filler, and applying the solution to the anodized layer. Applying the solution to the anodized layer includes submerging the anodized layer in the solution. Submerging the anodized layer in the solution preferably consists of submerging the anodized layer in the solution for at least approximately 5-10 minutes. To form a substrate for electrical circuits, the method next includes activating and then plating the unfilled region.

An integrated plated circuit heat sink constructed and arranged in accordance with the principle of the invention includes a non-ferrous metal substrate having a base surface, and an anodized layer applied to or otherwise formed on the base surface. The anodized layer has an outer surface to be plated, and an opposed inner surface applied to the base surface of the non-ferrous metal substrate. The anodized layer has a thickness from the outer surface thereof to the inner surface thereof. The anodized layer has a filled region and an unfilled region. The filled region is formed between the outer surface of the anodized layer and the inner surface of the anodized layer at the base surface of the non-ferrous metal substrate. The unfilled region is formed between the outer surface of the anodized layer and the filled region. Thus, the unfilled region of the anodized layer is formed atop the filled region of the anodized layer. The filled region and the unfilled region each have a thickness less than the thickness of the anodized layer. The thickness of the filled region is less than the thickness of the unfilled region in a particular embodiment of the invention. The filled region contains an electrically non-conductive micro-filler in that it is filled with the electrically non-conductive micro-filler characterizing it as a filled region. The unfilled region is not filled with the electrically non-conductive micro-filler thus characterizing it as an unfilled region. The unfilled region is activated or metalized and is then plated with conductive traces forming an integrated plated circuit heat sink, which exhibits excellent heat-dissipation properties and is rugged and resistant to heat and delamination. The provision of the filled region electrically isolating the unfilled region from the non-ferrous metal substrate prevents electrical leaking between the unfilled region and the non-ferrous metal substrate thus ensuring maximum operational efficiency of circuits and electronic components deposited on the unfilled region.

### BRIEF DESCRIPTION OF THE DRAWINGS

Referring to the drawings:

FIG. 1 is a highly generalized schematic section view of an integrated plated circuit heat sink constructed and arranged in accordance with the principle of the invention; and

FIG. 2 is an enlarged, highly generalized vertical section view of activated and filled regions of an anodized layer formed on a surface of a non-ferrous metal substrate in accordance with the principle of the invention.

### BEST MODES FOR CARRYING OUT THE INVENTION

Methods of plating an electrical circuit on an anodized layer formed on a surface of a non-ferrous metal substrate are disclosed. The non-ferrous metal substrate is preferably aluminum, and may also include other non-ferrous metals such as magnesium, titanium, or other selected non-ferrous metal. The anodized layer is conventionally formed on the non-ferrous metal substrate utilizing conventional anodizing processes well-known in the art. The anodized layer has an outer surface and an opposed inner surface at the surface, which is a base surface, of the non-ferrous metal substrate. The anodized layer is inherently porous and is filled with an electrically non-conductive micro-filler to form in the anodized layer a filled region between the outer and inner surfaces of the anodized layer, and leaving an unfilled region between the outer surface of the anodized layer and the filled region, whereby the filled region seals the anodized layer and electrically isolates the unfilled region of the anodized layer from the non-ferrous metal substrate preventing electrical leakage therebetween. The anodized layer is filled with the electrically non-conductive micro-filler by filling the pores inherent in the anodized layer with the electrically non-conductive micro-filler to form in the anodized layer the filled region. Filling the anodized layer with the electrically non-conductive micro-filler forms in the anodized layer the filled region in preparation for plating the unfilled region positioned atop the filled region. The unfilled region is not filled with the electrically non-conductive micro-filler and is electrically isolated from the base non-ferrous metal substrate by the filled region preventing electrical leakage between the unfilled region and the base non-ferrous metal substrate. Below the filled region is the surface or base surface of the base non-ferrous metal substrate, which functions as a heat sink. The unfilled region is activated or metalized, and then this activated unfilled region is plated with conductive traces to form a substrate for electrical circuits.

In accordance with the principle of the invention, a method of preparing a non-ferrous metal substrate for plating includes providing an anodized layer on a base surface of a non-ferrous metal substrate, the anodized layer having an outer surface and an opposed inner surface directed at the base surface of the non-ferrous metal substrate, and applying an electrically non-conductive micro-filler to the anodized layer to form in the anodized layer a filled region between the outer and inner surfaces of the anodized layer, and leaving an unfilled region of the anodized layer between the outer surface of the anodized layer and the filled region. The filled region is a region of the anodized layer filled with the non-conductive micro-filler, and the unfilled region is a region of the anodized layer that is not filled with the non-conductive micro-filler. The anodized layer is inherently porous, and the filled layer is characterized in that the pores of the filled region are filled with the electrically non-conductive micro-filler. The unfilled layer is characterized in that the pores of the unfilled region are not filled with the electrically non-conductive micro-filler. The filled region of the anodized layer electrically seals the anodized layer relative to the base surface of the non-ferrous metal substrate, and isolates the unfilled region of the anodized layer from the non-ferrous metal substrate preventing leakage of electrical current between unfilled region of the anodized layer and the non-ferrous metal substrate. The anodized layer is initially formed by conventional and well-known techniques, and has a preferred thickness of approximately 40-80 microns. Again, applying the electrically non-conductive micro-filler to the anodized layer fills the pores inherent in the anodized layer, which forms in the anodized layer the filled region. Below the filled region is the base of the non-ferrous metal substrate, which functions as a heat sink, and the unfilled region is available for plating to form a substrate for electrical circuits.

Applying the electrically non-conductive micro-filler to the anodized layer includes providing a solution of the electrically non-conductive micro-filler, and applying the solution of the non-conductive micro-filler to the anodized layer to form the filled region to electrically isolate the anodized layer from the non-ferrous metal substrate in preparation for activation or metalizing the anodized layer in preparation for plating, in accordance with the principle of the invention. The solution of the electrically non-conductive micro-filler is a filler solution. A preferred filler solution consists of 2 parts by volume of a lacquer, such as 2K P190-625 Nexa Brand lacquer, 1 parts by volume of a hardener, such as 2K P210-926 Nexa Brand hardener, and 0.5 part of a thinner, such as 2K P850-1493 Nexa Brand thinner. Electrically isolating the anodized layer from the non-ferrous metal substrate is carried out in the filler solution. Applying the filler solution to the anodized layer to form the filled region preferably includes submerging the anodized layer in the filler solution, which, in a preferred embodiment, is carried out by submerging the non-ferrous metal substrate in the filler solution. The anodized layer is submerged in the filler solution for a soaking duration of time sufficient to allow the filler solution to impregnate the anodized layer to fill a portion of the thickness of the anodized layer between the outer surface of the anodized layer and the inner surface of the anodized layer at the base surface of the non-ferrous metal substrate with the electrically non-conductive micro-filler to form the filled region between the outer and inner surfaces of the anodized layer and leaving an unfilled region of the anodized layer between the outer surface of the anodized layer and the filled region, whereby the filled region seals the anodized layer and electrically isolates the unfilled region of the anodized layer from the aluminum substrate preventing electrical leakage therebetween. The soaking duration of time is, in the present embodiment, at least approximately 5-10 minutes. This preferred soaking duration of time or soaking time ensures that the filler solution has enough time to impregnate the anodized layer to fill a portion of the thickness of the anodized layer between the outer surface of the anodized layer and the inner surface of the anodized layer at the base surface of the non-ferrous metal substrate with the electrically non-conductive micro-filler to form the filled region between the outer and inner surfaces of the anodized layer, while also leaving an unfilled region of the anodized layer between the outer surface of the anodized layer and the filled region. The term “at least approximately 5-10 minutes” means 5-10 minutes +/−30-45 seconds.

After submerging the anodized layer in the filler solution for the soaking duration of time sufficient to fill the anodized layer with the electrically non-conductive micro-filler to form in the anodized layer the filled region and leaving unfilled region of anodized layer according to the invention atop the filled region, the method next includes removing the anodized layer from the filler solution by simply removing the non-ferrous metal substrate from the filler solution, and drying the non-ferrous metal substrate and the anodized layer, preferably by leaving the non-ferrous metal substrate formed with the filled region to dry at room temperature for approximately 30-90 minutes leaving the electrically non-conductive micro-filler deposited in the anodized layer forming the filled region of the anodized layer according to the principle of the invention. Between the step of removing the anodized layer from the filler solution and the drying step in a preferred embodiment, the method still further includes removing excess filler solution from the filled region by wiping excess filler solution from the anodized layer, such as with a clean, dry, lint-free towel or squeegee or the like. To form a substrate for electrical circuits, the method next includes activating/metalizing the unfilled region of the anodized layer atop the filled region of the anodized layer in preparation for plating, and then plating the anodized layer at the unfilled region, which is considered a plating of the unfilled region.

The unfilled region is conventionally activated or metalized with a well-known and readily available solution of a palladium activator, and is then plated. After activation of the unfilled region, the unfilled region is an activated unfilled region.

Before activating the unfilled region, it may be masked with a selected or predetermined circuit pattern. Plating the activated unfilled region to form conductive traces is carried out after masking and after the unfilled region is activated. In accordance with a preferred embodiment, the unfilled region is plated first with a plating of nickel, and the plated nickel is then plated with copper, and the plated copper is then plated with nickel, and the plated nickel atop the plated copper is then plated with gold. Rather than gold, the plated copper layer atop the plated nickel layer may be free of an additional plated metal or, if desired, plated with silver, tin, or other suitable metal in lieu of gold. The plating processes are carried out in conventional and well-known metal baths in accordance with conventional and well-known plating techniques well-known to those having ordinary skill, and may be carried out singly or in a combination of plated layers.

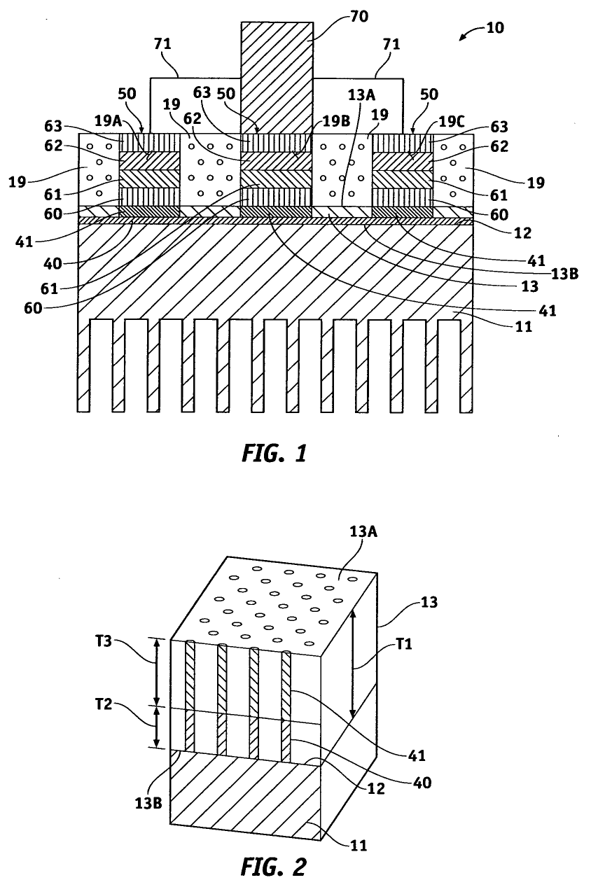

As a matter of example, FIG. 1 is a highly generalized schematic section view of an integrated plated circuit heat sink 10 constructed and arranged in accordance with the method set forth above including non-ferrous metal substrate 11 having base surface 12 formed with an anodized layer 13 having an outer surface 13A and an opposed inner surface 13B at base surface 12 of substrate 11. The non-conductive micro-filler is applied to anodized layer 13 at outer surface 13A to form in anodized layer a filled region 40 of anodized layer 13 and an unfilled region 41 of anodized layer 13 atop filled region 40. Surface 13A is formed with applied masking 19 to define areas 19A, 19B, and 19C to be traced with conductive traces. Filled and unfilled regions 40 and 41 are formed at each trace area 19A, 19B, and 19C.

Anodized layer 13 is inherently porous in that it has pores. FIG. 2 is a highly enlarged and highly generalized vertical section view of unfilled and filled regions 41 and 40, respectively, of anodized layer 13 formed on base surface 12 of substrate 11 in accordance with the principle of the invention. The vertical columns depicted in anodized layer 13 are generally representative of the pores inherent in anodized layer 13 and are shown for the purpose of illustration and reference.

Referencing FIG. 2, anodized layer 13 has a thickness T1 from outer surface 13A to inner surface 13B at base surface 12 of substrate 11. The thickness T1 of anodized layer 13 in FIG. 1 is exaggerated for illustrative purposes. Filled region 40 is formed on base surface 12. Filled region 40 is formed between outer surface 13A of anodized layer 13 and inner surface 13B of anodized layer 13 at base surface 12 of substrate 11 leaving atop filled region 40 unfilled region 41 between outer surface 13A of anodized layer 13 and filled region 40. Filled region 40 is formed at the bottom of anodized layer 13 along base surface 12 of substrate 11. Filled region 40 is formed between inner surface 13B of anodized layer 13 and unfilled region 41, and un-filled region 41 is formed between filled region 40 and outer surface 13A of anodized layer 13. Filled region 40 has thickness T2 of approximately 30 percent of the thickness T1 of anodized layer 13, and unfilled region 41 has a thickness T3 of approximately 70 percent of the thickness T1 of anodized layer 13. Thickness T2 of filled layer 40 and thickness T3 of unfilled layer 41 can be varied if desired. Thickness T2 is a bottom thickness of thickness T1 of anodized layer 13, and thickness T3 is a top thickness of thickness T1 of anodized layer 13. Filled region 40 seals anodized layer 13 and electrically isolates unfilled region 41 of anodized layer 13 from base surface 12 of substrate 11 preventing electrical leakage therebetween. Unfilled region 41 at each trace area 19A, 19B, and 19C is activated, namely, it is metalized with a palladium activator, and the activated or metalized unfilled region 41 at each trace area 19A, 19B, and 19C is then plated with conductive traces 50. Conductive traces 50 form part of a plated circuit.

According to the method set forth above, traces 50 each consist of a plated layer 60 of nickel applied to the metalized unfilled region 41, a plated layer 61 of copper applied to plated layer 60 of nickel, a plated layer 62 of nickel applied to plated layer 61 of copper, and a plated layer 63 of gold applied to plated layer 62 of nickel. Electrical component 70 is mounted on plated layer 63 of trace 50 at trace area 19B, and plated layers 63 of traces 50 at trace areas 19A and 19C are electrically connected to electrical component 70 with corresponding leads 71. This resulting integrated plated circuit heat sink 10 formed in accordance with the principle of the invention exhibits excellent heat-dissipation properties, and the provision of filled region 40 electrically isolates unfilled region 41 and outer surface 13A of anodized layer 13 at unfilled region 41 of anodized layer 13 from substrate 11 thereby preventing electrical leaking between outer surface 13A of unfilled region 41 of anodized layer 13 and substrate 11 thus ensuring maximum operational efficiency of the circuits and electronic components deposited on unfilled region 41.

The resulting integrated plated circuit heat sink 10 formed in accordance with the principle of the invention not only exhibits excellent heat-dissipation properties, but is also rugged, resists delamination, and is resistant to high operating temperatures. In a drop test, a 3×3×0.125 inch integrated plated circuit heat sink constructed and arranged in accordance with the principle of the invention was dropped from a height of seven feet onto a cement floor ten times and the performance of the integrated plated circuit heat sink was unaffected. In a delamination test, adhesive tape was applied across the plated surface of an integrated plated circuit heat sink constructed and arranged in accordance with the principle of the invention and pulled away at an angle of 45 degrees and delamination did not occur. In a temperature test, an integrated plated circuit heat sink constructed and arranged in accordance with the principle of the invention was baked in an oven at 260 degrees Celsius for 20-40 seconds, subjected to the drop test described above, and then subjected to the delamination test described above and the performance of the integrated plated circuit heat sink was unaffected.

The methods set forth in this specification provide a low cost integrated circuit packaging alternative, and may be carried out on one side of a non-ferrous metal substrate, opposed sides of a non-ferrous metal substrate, and on multiple sides of a multi-sided non-ferrous metal substrate having three or more sides.

The present invention is described above with reference to preferred embodiments. However, those skilled in the art will recognize that changes and modifications may be made in the described embodiments without departing from the nature and scope of the present invention. Various changes and modifications to the embodiments herein chosen for purposes of illustration will readily occur to those skilled in the art. To the extent that such modifications and variations do not depart from the spirit of the invention, they are intended to be included within the scope thereof.

Having fully described the invention in such clear and concise terms as to enable those skilled in the art to understand and practice the same, the invention claimed is:

1. In a non-ferrous metal substrate having an anodized layer thereon, a method of preparing the anodized layer for plating comprising electrically isolating the anodized layer from the non-ferrous metal substrate in a solution of an electrically non-conductive micro-filler.

2. A method according to claim 1, wherein the step of electrically isolating the anodized layer from the non-ferrous metal substrate in the solution of the electrically non-conductive micro-filler further comprises:
submerging the anodized layer in the solution for at least approximately 5-10 minutes;
removing the anodized layer from the solution; and
drying the anodized layer.

3. A method according to claim 2, further comprising removing excess solution from the anodized layer between the removing and drying steps.

4. A method according to claim 3, wherein the step of removing excess solution from the anodized layer further comprises wiping excess solution from the anodized layer.

5. A method according to claim 1, further comprising activating the anodized layer.

6. A method according to claim 5, further comprising plating the anodized layer.

7. A substrate for electrical circuits made in accordance with the method of claim 6.

8. A method of preparing a non-ferrous metal substrate for plating, comprising steps of:
providing an anodized layer on a non-ferrous metal substrate, the anodized layer having an outer surface and an opposed inner surface directed at the non-ferrous metal substrate;
applying an electrically non-conductive micro-filler to the anodized layer to form in the anodized layer a filled region between the outer and inner surfaces of the anodized layer, and an unfilled region between the outer surface of the anodized layer and the filled region; and
the filled region of the anodized layer electrically isolating the unfilled region of the anodized layer from the non-ferrous metal substrate.

9. A method according to claim 8, where in the step of applying the electrically non-conductive micro-filler comprises:
providing a solution of the electrically non-conductive micro-filler; and
applying the solution to the anodized layer.

10. A method according to claim 9, wherein the step of applying the solution to the anodized layer further comprises submerging the anodized layer in the solution.

11. A method according to claim 10, wherein the step of submerging the anodized layer in the solution further comprises submerging the anodized layer in the solution for at least approximately 5-10 minutes.

12. A method according to claim 8, further comprising activating the unfilled region.

13. A method according to claim 12, further comprising plating the unfilled region.

14. A substrate for electrical circuits made in accordance with the method of claim 13.
